(19) United States
(12) Patent Application Publication
(10) Pub. No.: US 2014/0140128 A1
(43) Pub. Date: May 22, 2014

(54) Processors and Systems with Divided-Down Phase Change Memory Read Voltages

(71) Applicant: Being Advanced Memory Corporatoin, (US)

(72) Inventor: Ryan Jurasek, Burlington, VT (US)

(73) Assignee: Being Advanced Memory Corporatoin, Essex Junction, VT (US)

(21) Appl. No.: 13/869,752

(22) Filed: Apr. 24, 2013

Related U.S. Application Data
(60) Provisional application No. 61/637,331, filed on Apr. 24, 2012.

(51) Int. Cl. G11C 13/00

(52) U.S. Cl. CPC G11C 13/004
USPC 365/163

(57) ABSTRACT

Methods and systems for fast, low power PCM memory using a bitline precharge scheme in which unselected bitlines are driven to predetermined voltages and a selected bitline is set to ground, such that when selected and unselected bitlines are shorted together, the selected bitline is charged to a PCM sense voltage. Inventive methods and systems do not require a precharge voltage regulator to drive selected bitlines to a sense voltage.

### CROSS-REFERENCE

Priority is claimed from U.S. Provisional Patent No. 61/637,331, which is hereby incorporated by reference.

### BACKGROUND

The present application relates to phase change memories, and to systems or larger chips which use them, as well as to related methods of operation; and most especially relates to how read operations are conducted.

Note that the points discussed below may reflect the hindsight gained from the disclosed inventions, and are not necessarily admitted to be prior art.

Phase change memory (“PCM”) is a relatively new nonvolatile memory technology, which is very different from any other kind of nonvolatile memory. First, the fundamental principles of operation, at the smallest scale, are different: no other kind of solid-state memory uses a reversible PHYSICAL change to store data. Second, in order to achieve that permanent physical change, an array of PCM cells has to allow read, set, and reset operations which are all very different from each other. The electrical requirements of the read, set, and reset operations make the peripheral circuit operations of a PCM very different from those of other nonvolatile memories. Obviously some functions, such address decoding and bus interface, can be the same; but the closest-in parts of the periphery, which perform set, reset, and read operations on an array or subarray, must satisfy some unique requirements.

The physical state of a PCM cell's memory material is detected as resistance. For each selected cell, its bitline is set to a known voltage, and the cell's access transistor is turned on (by the appropriate wordline). If the cell is in its low-resistance state, it will sink a significant current from the bit line; if it is not, it will not.

Set and Reset operations are more complicated. Both involve heat. As discussed below, a “set” operation induces the memory material to recrystallize into its low-resistance (polycrystalline) state; a “reset” operation anneals the memory material into its high-resistance (amorphous) state.

Write operations (Set and Reset) normally have more time budget than read operations. In read mode a commercial PCM memory should be competitive with the access speed (and latency if possible) of a standard DRAM. If this degree of read speed can be achieved, PCM becomes very attractive for many applications.

The phase change material is typically a chalcogenide glass, using amorphous and crystalline (or polycrystalline) phase states to represent bit states.

A complete PCM cell can include, for example: a top electrode (connected to the bit line), a phase change material (e.g. a chalcogenide glass), a conductive pillar which reaches down from the bottom of the phase change material, an access transistor (gated by a word line), and a bottom connection to ground. The phase change material can extend over multiple cells (or over the whole array), but the access transistors are laterally isolated from each other by a dielectric.

FIG. 2A shows an example of a PCM element 2010. A top electrode 2020 overlies a phase change material 2030, e.g. a chalcogenide glass. Note that material 2030 also includes a mushroom-shaped annealed zone (portion) 2070 within it. (The annealed zone 2070 may or may not be present, depending on what data has been stored in this particular location.) The annealed zone 2070, if present, has a much higher resistivity than the other (crystalline or polycrystalline) parts of the material 2030.

A conductive pillar 2050 connects the material 2030 to a bottom electrode 2040. In this example, no selection device is shown; in practice, an access transistor would normally be connected in series with the phase change material. The pillar 2050 is embedded in an insulator layer 2060.

When voltage is applied between the top 2020 and bottom 2040 electrodes, the voltage drop will appear across the high-resistivity zone 2070 (if present). If sufficient voltage is applied, breakdown will occur across the high-resistivity zone. In this state the material will become very conductive, with large populations of mobile carriers. The material will therefore pass current, and current crowding can occur near the top of the pillar 2050. The voltage which initiates this conduction is referred to as the “snapback” voltage, and FIG. 2C shows why.

FIG. 2C shows an example of instantaneous I-V curves for a device like that of FIG. 2A, in two different states. Three zones of operation are marked.

In the zone 2200 marked “READ,” the device will act either as a resistor or as an open (perhaps with some leakage). A small applied voltage will result in a state-dependent diffrence in current, which can be detected.

However, the curve with open circles, corresponding to the amorphous state of the device, shows some more complex behaviors. The two curves show behaviors under conditions of higher voltage and higher current.

If the voltage reaches the threshold voltage Vₜₕ, current increases dramatically without any increase in voltage. (This occurs when breakdown occurs, so the phase-change material suddenly has a large population of mobile carriers.) Further increases in applied voltage above Vₜₕ result in further increases in current; note that this upper branch of the curve with hollow circles shows a lower resistance than the curve with solid squares.

If the applied voltage is stepped up to reach the zone 2150, the behavior of the cell is now independent of its previous state.

When relatively large currents are applied, localized heating will occur at the top of the pillar 2050, due to the relatively high current density. Current densities with typical dimensions can be in the range of tens of millions of Amperes per square cm. This is enough to produce significant localized heating within the phase-change material.

This localized heating is used to change the state of the phase-change material, as shown in FIG. 2B. If maximum current is applied in a very brief pulse 2100 and then abruptly stopped, the material will tend to quench into an amorphous high-resistivity condition; if the phase-change material is cooled more gradually and/or not heated as high as zone 2150, the material can recrystallize into a low-resistivity condition. Conversion to the high-resistance state is normally referred to as “Reset”, and conversion to the low-resistance state is normally referred to as “Set” (operation 2080). Note that, in this example, the Set pulse has a tail where current is reduced fairly gradually, but the Reset pulse does not. The duration of the Set pulse is also much longer than that of the Reset pulse, e.g. tens of microseconds versus hundreds of nanoseconds.

FIG. 2D shows an example of temperature versus resistivity for various PCM materials. It can be seen that each curve has a notable resistivity drop 2210 at some particular temperature. These resistivity drops correspond to phase change to a crystalline (or polysilicon) state. If the material is cooled gradually, it remains in the low resistivity state after cooling.

In a single-bit PCM, as described above, only two phases are distinguished: either the cell does or does not have a significant high-resistivity “mushroom cap” 2070. However, it is also possible to distinguish between different states of the mushroom cap 2070, and thereby store more than one bit per cell.

FIG. 2E shows an equivalent circuit for an “upside down” PCM cell 2010. In this example the pass transistor 2240 is gated by Wordline 2230, and is connected between the phase-change material 2250 and the bitline 2220. (Instead, it is somewhat preferable to connect this transistor between ground and the phase-change material.

FIG. 2F shows another example of a PCM cell 2010. A bitline 2220 is connected to the top electrode 2020 of the phase-change material 2250, and transistor 2240 which is connected to the bottom electrode 2030 of the PCM element. (The wordline 2230 which gates the vertical transistor 2240 is not shown in this drawing.) Lines 2232, which are shown as separate (and would be in a diode array), may instead be a continuous sheet, and provide the ground connection.

FIG. 2G shows an example of resistance (R) over time (t) for a single PCM cell following a single PCM write event at time t=0. The resistance curve 2400 for a cell which has been reset (i.e. which is in its high-resistance state) may rise at first, but then drifts significantly lower. The resistance curve 2410 for a cell in the Set state is much flatter. The sense margin 2420, i.e., the difference between set and reset resistances, also decreases over time. Larger sense margins generally result in more reliable reads, and a sense margin which is too small may not permit reliable reading at all. 2G represents the approximate behavior of one known PCM material; other PCM material compositions may behave differently. For example, other PCM material compositions may display variation of the set resistance over time.

The downwards drift of reset resistance may be due to, for example, shrinking size of the amorphous zone of the phase-change material, due to crystal growth; and, in some cells, spontaneous nucleation steepening the drift curve (possibly only slightly) due to introducing further conductive elements into the mushroom-shaped programmable region.

FIG. 2H shows an example of a processing system 2300. Typically, a processing system 2300 will incorporate at least some of interconnected power supplies 2310, processor units 2320 performing processing functions, memory units 2330 supplying stored data and instructions, and I/O units 2340 controlling communications internally and with external devices 2350.

FIG. 2I shows an example of a PCM single ended sensing memory. Two different PCM cells 2400 on different ends of a sense amplifier can be selected separately. Selected elements 2410 are separately sensed by a single-ended sense amplifier 2420.

FIG. 2J shows an example of a known PCM single ended sense amplifier 2500. Generally, in a single ended sense amplifier, a cell read output conducted by a selected bitline BLB is compared against a reference current to provide a digital output OUT. When the PRECHARGE signal turns on transistor 2530, voltage V04 (e.g., 400 mV) precharges the bitline BLB. After precharge ends, the READ signal turns on transistor 2550. Transistor 2550 is connected, through source follower 2560 and load 2580, to provide a voltage which comparator 2600 compares to Voltage_REF, to thereby generate the digital output OUT.

A variety of nonvolatile memory technologies have been proposed over recent decades, and many of them have required some engineering to provide reference values for sensing. However, the requirements and constraints of phase-change memory are fundamentally different from those of any other kind of nonvolatile memory. Many memory technologies (such as EEPROM, EPROM, MNOS, and flash) test the threshold voltage of the transistor in a selected cell, so referencing must allow for the transistor's behavior. By contrast, phase-change memory simply senses the resistance of the selected cell. This avoids the complexities of providing a reference which will distinguish two (or more) possibilities for an active device's state, but does require detecting a resistance value, and tracking external variations (e.g. temperature and supply voltage) which may affect the instantaneous value of that resistance.

The possibility of storing more than one bit of data in a single phase-change material has also been suggested. Phase-change memories implementing such architectures are referred to here as “multibit” PCMs. If the “Set” and/or “Reset” operations can be controlled to produce multiple electrically distinguishable states, then more than one bit of information can be stored in each phase-change material location. It is known that the current over time profile of the Set operation can be controlled to produce electrically distinguishable results, though this can be due to more than one effect. In the simplest implementation, shorter anneals—too short to produce full annealing of the amorphous layer—can be used to produce one or more intermediate states. In some materials, different crystalline phases can also be produced by appropriate selection of the current over time profile. However, what is important for the present application is merely that electrically distinguishable states can be produced.

For example, if the complete layer of phase-change material can have four possible I/V characteristics, two bits of information can be stored in each cell—IF the read cycle can accurately distinguish among the four different states.

(The I/V characteristics of the cells which are not in the fully Set state are typically nonlinear, so it is more accurate to distinguish the states in terms of current flow at a given voltage; resistance is often used as a shorthand term, but implies a linearity which may not be present.)

In order to make use of the possible multibit cell structures, it is necessary to reliably distinguish among the possible states. To make this distinction reliably, there must be some margin of safety, despite the change in characteristics which may occur due to history, manufacturing tolerances, and environmental factors. Thus the read architecture of multibit PCMs is a far more difficult challenge it is for PCMs with single-bit cells.

### SUMMARY

The current application discloses new approaches to phase change memory arrays, subarrays, memory chips, embedded memory blocks, and to systems or larger chips which use phase-change memory, as well as to related methods of operation. In particular, methods for reading data are improved.

Phase-change memory (PCM) arrays can make use of read voltages which are much smaller than the voltages required for write operations. Moreover, lower read voltages help reduce power consumption. Conventionally bitline precharge is accomplished by using a separate voltage regulator to provide the read voltage.

The phase-change material at the heart of a PCM cell is not a linear resistor (unless it is in its fully crystallized state). Instead, the current passed by a phase-change material will depend exponentially on the applied voltage. Accuracy in the read voltage (i.e. the voltage precharged onto the bit line before the access transistors are turned on) is therefore critical. This is a different challenge than has been faced by other memory technologies.

The present application provides a way to accelerate the precharge phase of read operations, while also avoiding the need for one of the regulated supply voltages. Instead of regulating down to provide the (small) read voltage, only some bitlines are precharged to supply voltage (or to an existing regulated voltage which has a low source impedance, e.g. which is stabilized by large capacitors), while others are grounded. To precharge bitlines for a read operation, multiple (or all) bitlines can then be shorted together, to quickly provide the required read voltage. Thus the bitlines collectively act as a capacitive voltage divider.

In one advantageous implementation, selection of how many bitlines to use for capacitive dividing, and how many of those are connected to supply and/or how many to ground, can be a configuration option, so that read voltage can be trimmed.

As a result, no precharge voltage regulator is required, saving current expenditure. Further, unselected bitlines can be recharged from an elevated voltage level after the short is deactivated, further saving current (and, thus, power) cost. A further advantage is that, since an available voltage can be divided down by whatever fraction is desired, a voltage which is already regulated can be used as the starting point. This improves rejection of supply noise.

The disclosed innovations, in various embodiments, provide one or more of at least the following advantages. However, not all of these advantages result from every one of the innovations disclosed, and this list of advantages does not limit the various claimed inventions.
Does not require a precharge voltage regulator;
lower power consumption for PCM memories;
lower power consumption for devices incorporating PCM memories;
lower latency PCM memories;
higher data rate PCM memories; and
devices incorporating PCM memories are faster.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1 shows a simplified example of an innovative bitline precharge circuit.

FIG. 2A shows an example of a PCM element.

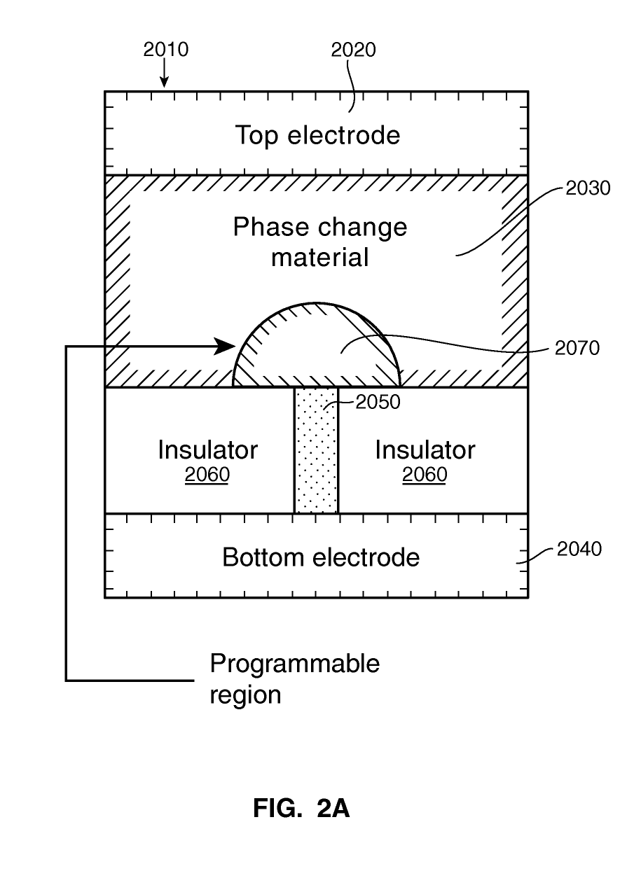

FIG. 2B shows an example of PCM bit line signals.

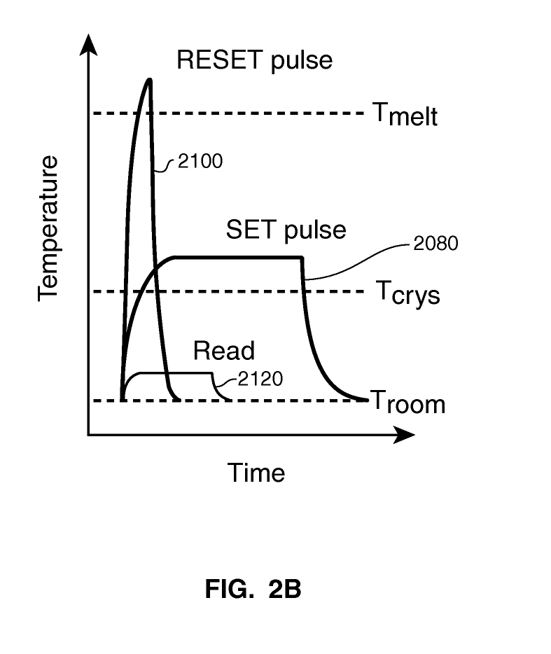

FIG. 2C shows an example of voltage versus current in a PCM material.

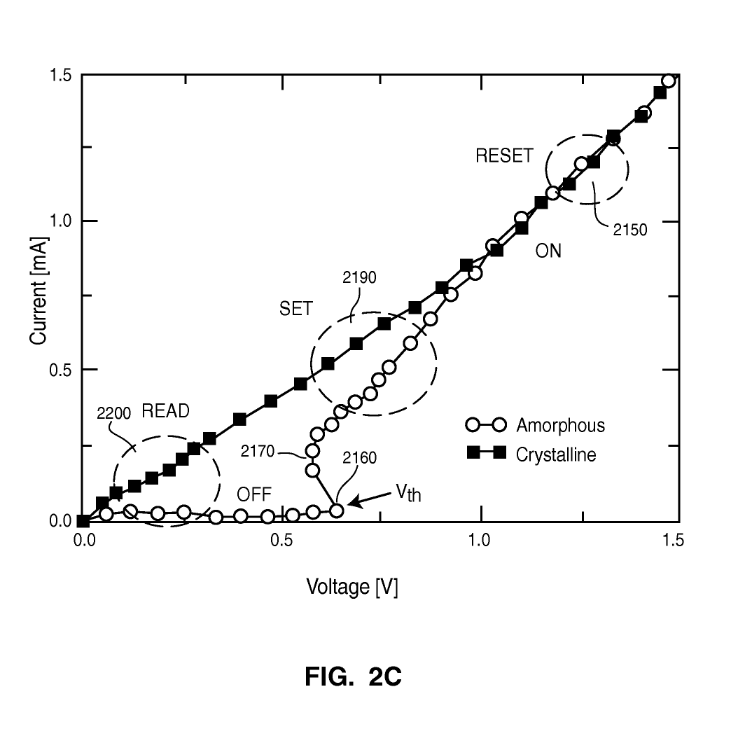

FIG. 2D shows an example of temperature versus resistance in a PCM material.

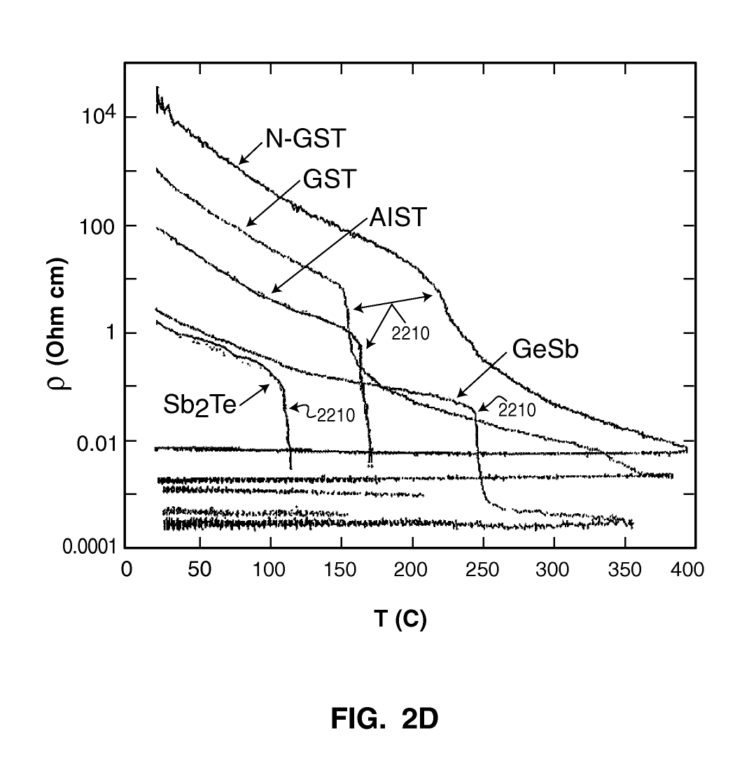

FIG. 2E shows an example of a PCM cell.

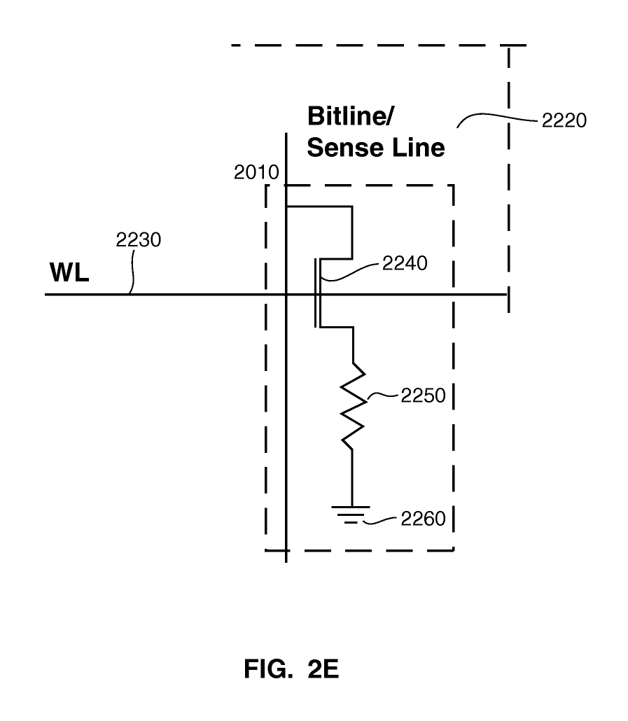

FIG. 2F shows an example of a PCM cell.

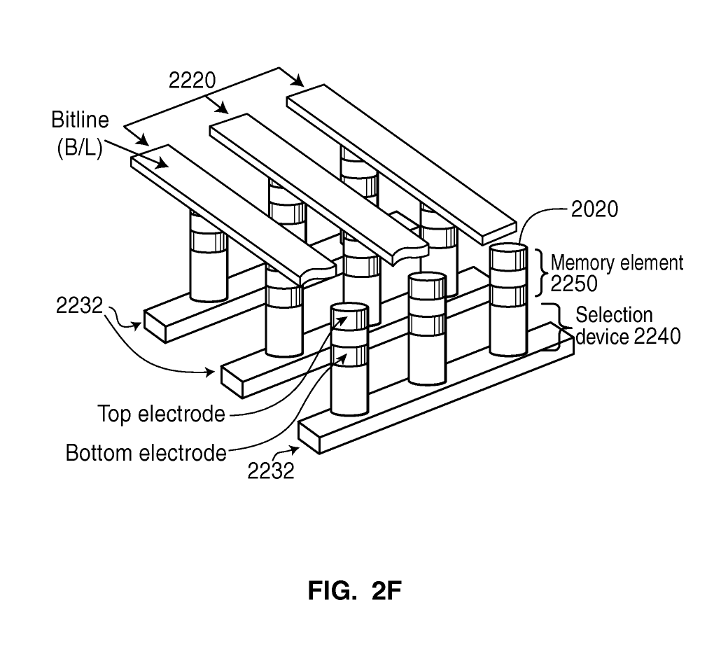

FIG. 2G shows an example of resistance over time for a PCM cell.

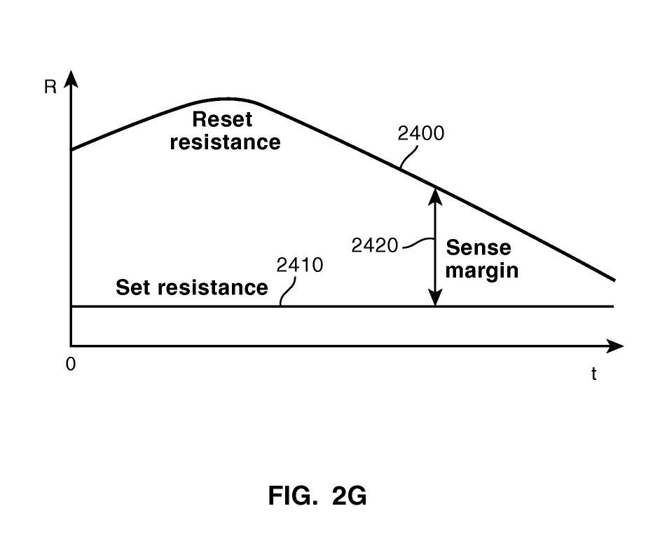

FIG. 2H shows an example of a processing system.

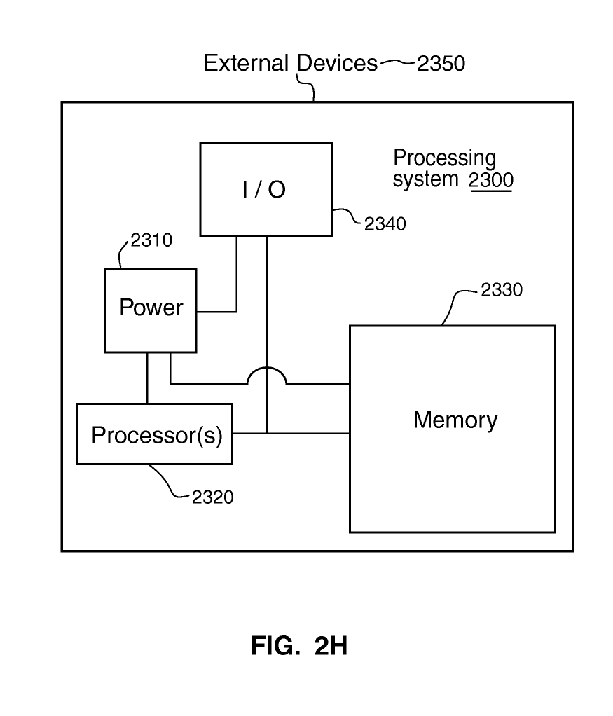

FIG. 2I shows an example of a PCM single ended sensing memory.

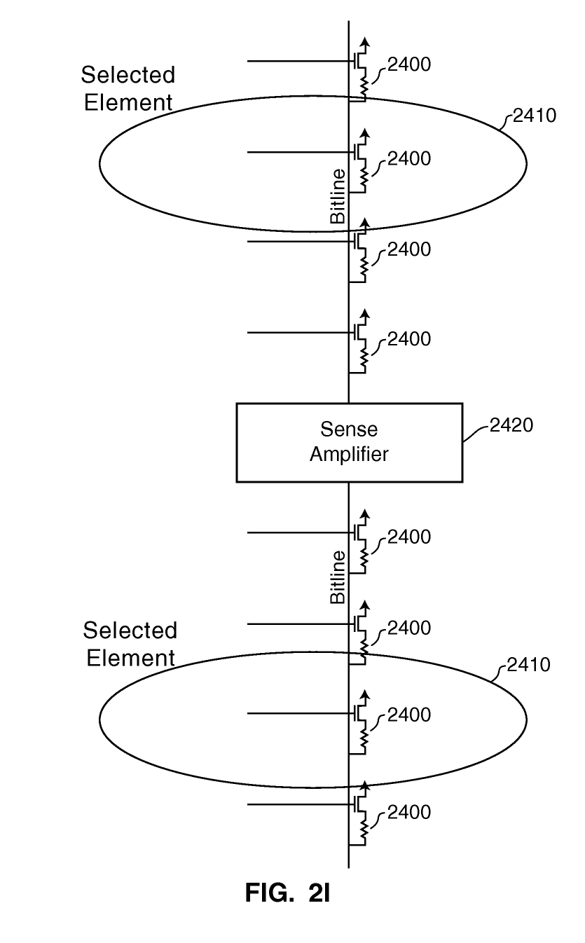

FIG. 2J shows an example of a known PCM single ended sense amplifier.

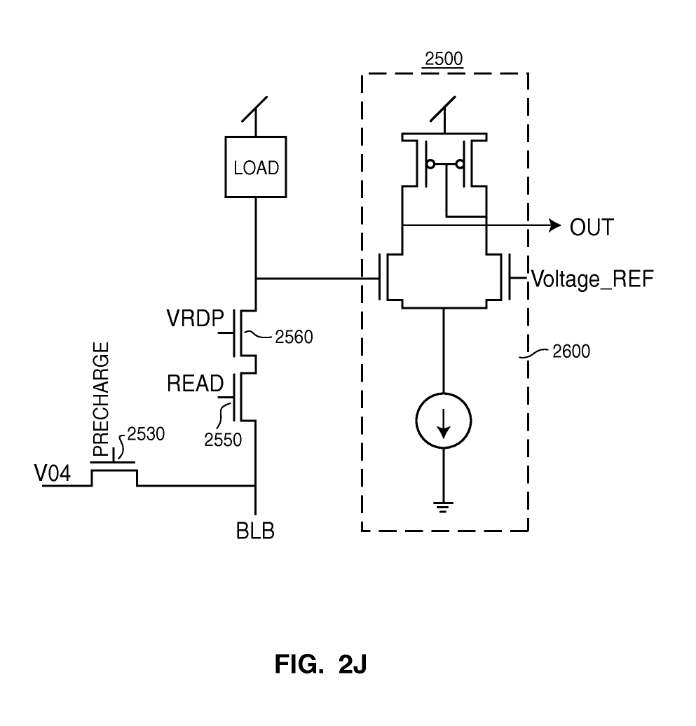

FIG. 3 shows an example of the rapid precharge operation which is achieved using the circuit of FIG. 1.

FIG. 4 shows an example of a known bitline precharge circuit, and FIG. 5 shows an example of a voltage-time curve from a configuration like that of FIG. 4.

FIG. 6 shows a source-follower precharge circuit, and the resulting slow precharge operation.

FIG. 7 shows an active bitline precharge circuit. This provides rapid precharge, but has the disadvantages of: mismatch; high power consumption; and large area.

FIG. 8 shows an example of a floor plan 300 for a complete PCM chip, which advantageously can incorporate bitline precharge circuits like that of FIG. 1.

FIG. 9 shows an example of a portion of the PCM memory of FIG. 8.

FIG. 10 shows a different view of a portion of a PCM memory.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

In some PCM memories, the time between array accesses is sufficient to charge one or more unselected bitlines to a voltage well above a PCM read voltage. Precharge voltage regulators can draw significant power during the precharge and bitline shorting process, both by their nature as circuitry, and because of the amplifier response to current demand when the voltage drops immediately after shorting to a selected bitline, requiring the voltage to be regulated higher.

The present inventors realized that because different bitlines typically have approximately the same capacitance, different voltages on different bitlines will average out predictably when said bitlines are shorted together. By precharging only one quarter of the bitlines in the area to an internal regulated voltage, and tieing the other bitlines to ground, the voltage when all bitlines are shorted together will rapidly equilibrate to one quarter of the supply voltage.

Following are some quantitative examples for a 2012-era PCM:

External supply voltage: 1.8V;
Supply to sense amps: 1.8V
Supply to logic and peripherals: 1.2V (regulated from external supply);
Read voltage: 0.4V (400 mV) (regulated from 1.8V);
“Set” voltage: 2.5V (boosted from 1.8V);
“Reset” voltage: 3.5V (boosted from 1.8V).

The present application provides a way to accelerate the precharge phase of read operations, and avoid the need for one of the regulated supply voltages. Instead of regulating down to provide the (small) read voltage, only some bitlines are precharged to supply voltage (or to an existing regulated voltage which has a low source impedance, e.g. which is stabilized by large capacitors), while others are grounded. To precharge bitlines for a read operation, multiple (or all) bitlines can then be shorted together, to quickly provide the required read voltage. Thus the bitlines collectively act as a capacitive voltage divider.

The exact fraction of bitlines to be precharged will depend on the desired read voltage, and on the available voltages on-chip. Since the charged bitlines are connected in parallel, and have the lowest possible resistance to the bitlines which are not precharged, this arrangement provides a low source impedance, and a very low RC time constant.

It is not necessary to precharge or ground all bitlines in the array. For example, if the read precharge configuration permits up to four bitlines to be used for charge sharing with the selected bitline, then the read voltage can be selected to be anywhere from 20% (one line charged, three at ground) to 80% (all four lines charged) of the local supply voltage which is used for the bitlines.

In one advantageous implementation, selection of how many bitlines to use for capacitive dividing, and how many of those are connected to supply and/or how many to ground, can be a configuration option, so that read voltage can be trimmed.

As a result, no precharge voltage regulator is required, saving on current expenditure. Further, unselected bitlines can be recharged from an elevated voltage level after the short is deactivated, further saving current (and, thus, power) cost.

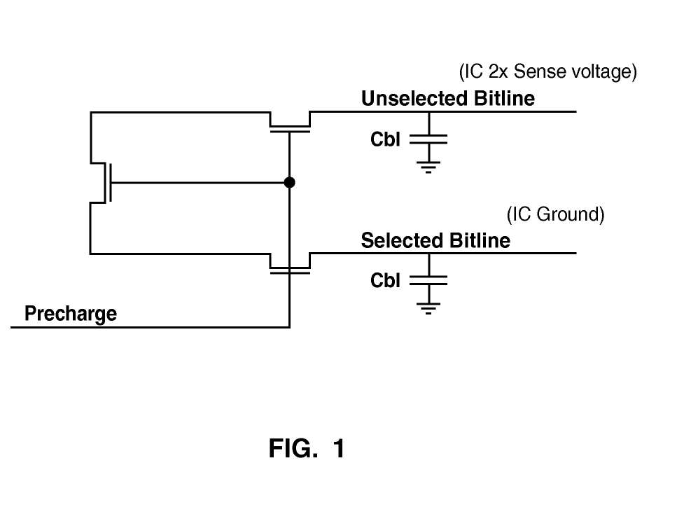

FIG. 1 shows a simplified example of an innovative bitline precharge circuit. This portion shows only the precharge portion of two bitlines, together with the shorting transistor which connects those two bitlines together. In the example shown the shorting transistor is turned on at the same time as the precharge transistors, but alternatively these gate lines can be separated. By precharging only some fraction of the bitlines to the available high voltage, a precisely controlled read voltage is achieved. In this example, the regulated voltage of 1.2V is used as the starting point for capacitive voltage dividing, so one third of the bitlines are precharged to 1.2V before shorting, and two thirds of the bitlines are at ground.

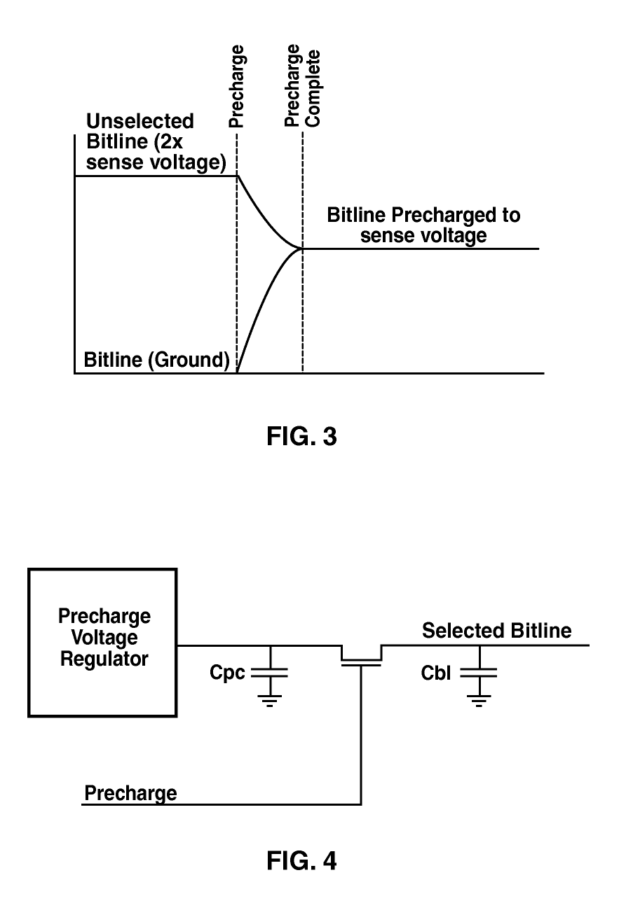

FIG. 3 shows an example of the rapid precharge operation which is achieved using the circuit of FIG. 1.

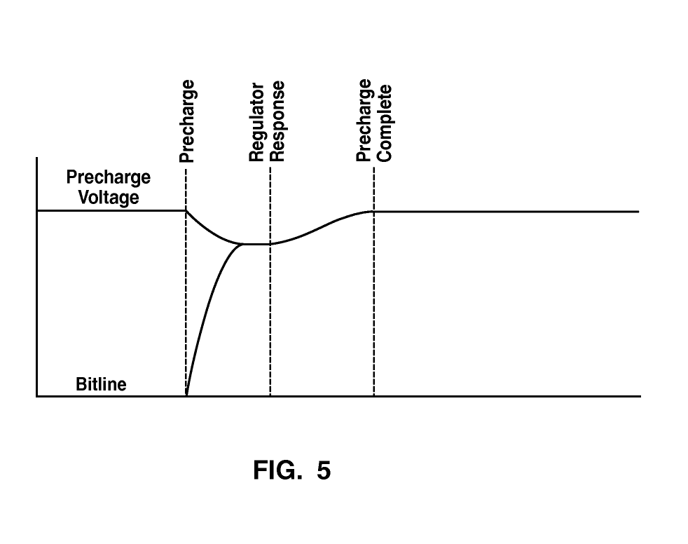

FIG. 4 shows an example of a known bitline precharge circuit, and FIG. 5 shows an example of a voltage-time curve from a configuration like that of FIG. 4. Since the parasitic bitline capacitance Cb1 is quite significant, the last part of the process takes a significant amount of time.

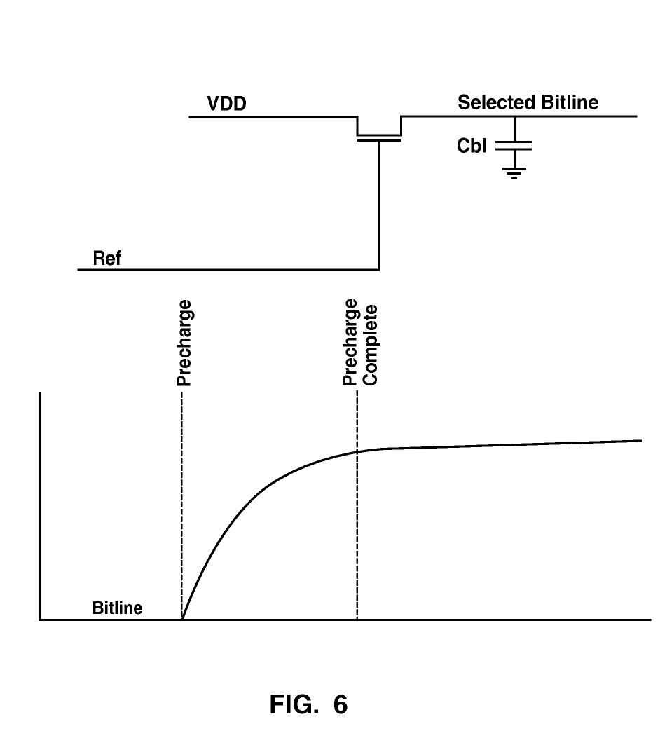

FIG. 6 shows a source-follower precharge circuit. As can be seen, the resulting precharge operation is very slow.

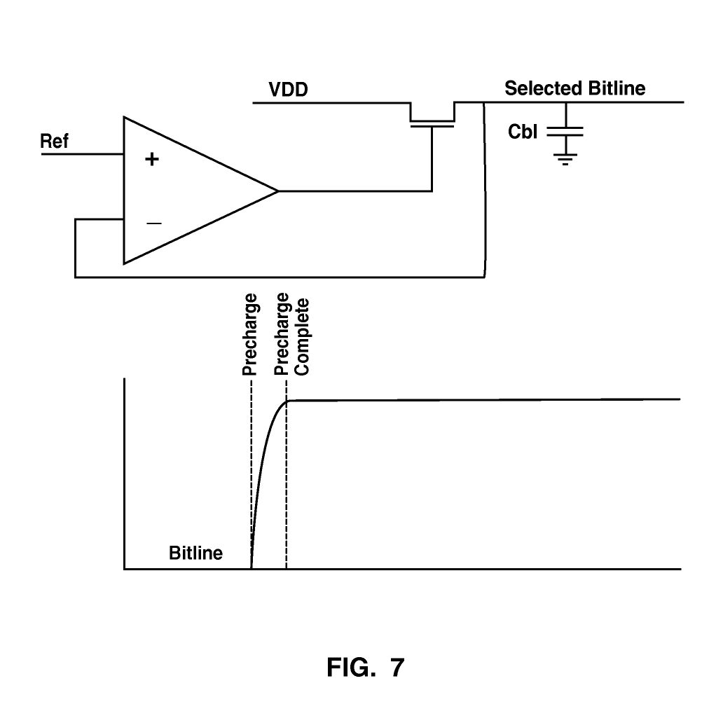

FIG. 7 shows an active bitline precharge circuit. This provides rapid precharge, but has the disadvantages of: mismatch; high power consumption; and large area.

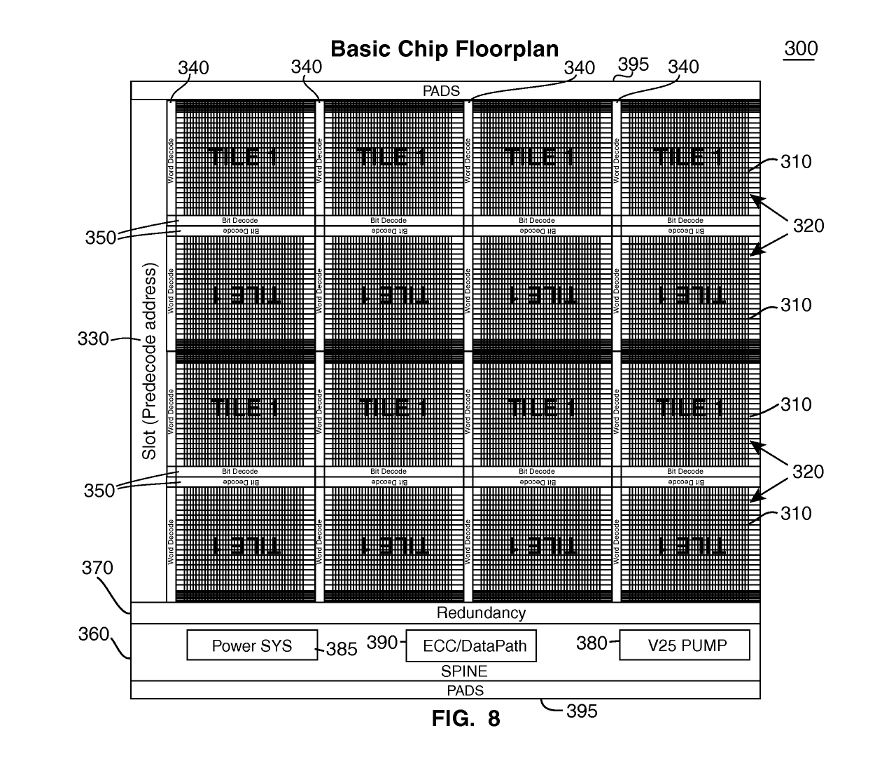

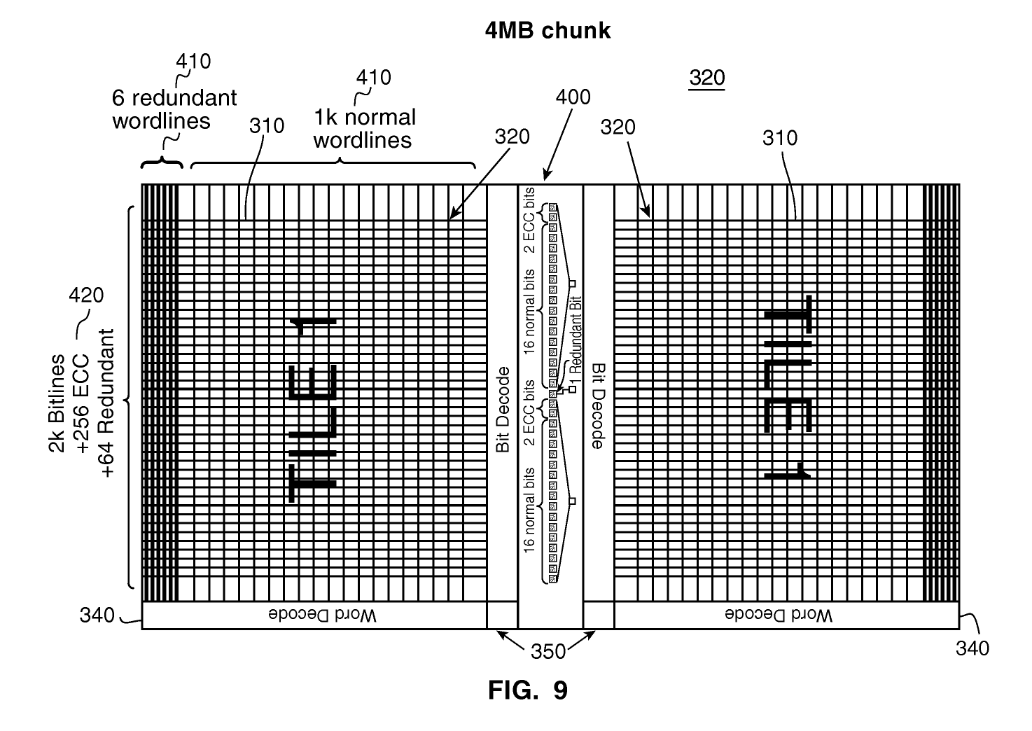

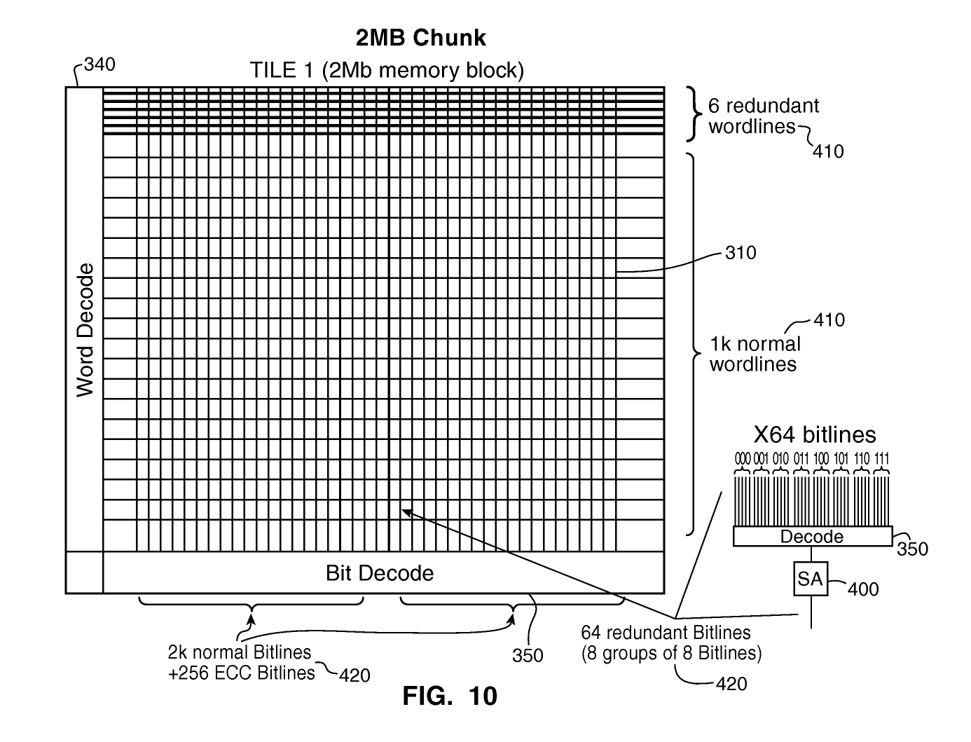

FIG. 8 shows an example of a floor plan 300 for a complete PCM chip, which can advantageously which can incorporate bitline precharge circuits like that of FIG. 1. Tiles 310 are memory portions that can be implemented e.g. as shown in FIG. 10. Tile pairs 320 are memory portions that can be implemented e.g. as shown in FIG. 9. The SLOT area 330 includes logic for taking a predecode address, splitting it into wordline and bitline components, and sending the wordline and bitline components to the corresponding word decode (340) and bit decode (350) logic in the corresponding memory tiles 310 (TILE 1).

The Spine area 360 includes redundancy logic 370, which compares addresses received by the memory to permanently programmed redundancy information to determine when a memory access needs to be redirected to redundancy memory components. Also located here is a voltage pump 380 (which produces 2.5V in this example). Block 385 block contains reference and regulated power (voltage and current) supplies. ECC/DataPath block 390 uses error correction code bits for repairing soft memory fails. Datapath logic that interprets data, encodes it into an output format (e.g., serial) and streams it out of the chip. Pad locations 395 are also shown, and multiple contact pads would typically be located in each.

FIG. 9 shows an example of a portion of the PCM memory of FIG. 8. Two tiles 320. Two 2 MB chunks of memory 310 (Tiles) are tiled together to share 37 sense amplifiers, which include 32 normal sense amplifiers, 4 for error correction (ECC), and 1 for redundancy (Redundant Bit). Numbers of normal, ECC and redundancy sense amplifiers 400 can be different in other embodiments. This Figure also shows an example allocation of space to various structures.

FIG. 10 shows a different view of a portion of a PCM memory. The 2 MB chunk of memory 310 (Tile) shown comprises 1024 normal and 6 redundant wordlines 410 accessed using Word Decode 340 logic that, inter alia, decodes a word portion of an address received by the memory into a word portion of an address of a corresponding group; and 2048 normal, 256 ECC (error correction code) and 64 Redundant (in 8 groups of 8) Bitlines 420 accessed using Bit Decode 350 logic that, inter alia, decodes a bitline portion of an address received by the memory into a bitline portion of an address of a corresponding group.

According to some but not necessarily all disclosed embodiments, there is provided: A phase-change memory, comprising: a plurality of bitlines; a plurality of phase-change memory cells, each connected to one of said bitlines; and read circuitry configured such that, at the start of a read operation, a first predetermined fraction of the bitlines are initially connected to ground, and a second predetermined fraction of the bitlines are initially connected to an internal supply voltage; and thereafter a plurality or all of the bitlines are shorted together, to rapidly provide a precharge voltage which is proportional to the internal supply voltage, with a ratio determined by said first and second predetermined fractions; said read circuitry thereafter activating at least one row of said phase-change memory cells.

According to some but not necessarily all disclosed embodiments, there is provided: A method of reading PCM cells, comprising: at the start of a read operation, connecting a first predetermined fraction of the bitlines which connect to phase-change memory cells in a subarray to ground, and connecting a second predetermined fraction of the bitlines are to an internal supply voltage; and thereafter shorting a plurality or all of the bitlines together, to rapidly provide a precharge voltage which is proportional to the internal supply voltage, with a ratio determined by said first and second predetermined fractions; and thereafter activating at least one row of said phase-change memory cells.

According to some but not necessarily all disclosed embodiments, there is provided: Methods and systems for fast, low power PCM memory using a bitline precharge scheme in which unselected bitlines are driven to predetermined voltages and a selected bitline is set to ground, such that when selected and unselected bitlines are shorted together, the selected bitline is charged to a PCM sense voltage. No precharge voltage regulator is required to drive selected bitlines to a sense voltage.

According to some but not necessarily all disclosed embodiments, there is provided: A system incorporating phase-change memory, comprising: at least one programmable logic device; and a plurality of phase-change memory cells, each connected to one of a plurality of bitlines; and read circuitry configured such that, at the start of a read operation, a first predetermined fraction of the bitlines are initially connected to ground, and a second predetermined fraction of the bitlines are initially connected to an internal supply voltage; and thereafter a plurality or all of the bitlines are shorted together, to rapidly provide a precharge voltage which is proportional to the internal supply voltage, with a ratio determined by said first and second predetermined fractions; said read circuitry thereafter activating at least one row of said phase-change memory cells; wherein said programmable logic device is configured and programmed to store information in said phase-change memory, and to retrieve information from said phase-change memory at power-up.

According to some but not necessarily all disclosed embodiments, there is provided: A method for operating a system which includes phase-change memory cells, comprising: controlling output lines, and reading data inputs, using at least one programmable logic device; reading and writing a phase-change memory with said programmable logic device; at the start of a read operation, connecting a first predetermined fraction of the bitlines which connect to phase-change memory cells in a subarray of the phase-change memory to ground, and connecting a second predetermined fraction of the bitlines are to an internal supply voltage; and thereafter shorting a plurality or all of the bitlines together, to rapidly provide a precharge voltage which is proportional to the internal supply voltage, with a ratio determined by said first and second predetermined fractions; and thereafter activating at least one row of said phase-change memory cells to read data which is then communicated to said logic device.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

For example, different supply voltages can be used, or different division ratios. Moreover, different bitlines can be precharged to different voltages if desired.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

Additional general background, which helps to show variations and implementations, as well as some features which can be synergistically with the inventions claimed below, may be found in the following US patent applications. All of these applications have at least some common ownership, copendency, and inventorship with the present application, and all of them are hereby incorporated by reference: U.S. Provisionals 61/637,331; 61/637,496; 61/637,513; 61/637,518; 61/637,526; 61/637,533; 61/638,217; 61/694,217; 61/694,220; 61/694,221; 61/694,223; 61/694,224; 61/694,225; 61/694,228; 61/694,234; 61/694,240; 61/694,242; 61/694,243; and 61/694,245.

The claims as filed are intended to be as comprehensive as possible, and NO subject matter is intentionally relinquished, dedicated, or abandoned.

What is claimed is:

1. A system incorporating phase-change memory, comprising:
at least one programmable logic device; and
a plurality of phase-change memory cells, each connected to one of a plurality of bitlines; and read circuitry configured such that, at the start of a read operation, a first predetermined fraction of the bitlines are initially connected to ground, and a second predetermined fraction of the bitlines are initially connected to an internal supply voltage; and thereafter a plurality or all of the bitlines are shorted together, to rapidly provide a precharge voltage which is proportional to the internal supply voltage, with a ratio determined by said first and second predetermined fractions;
said read circuitry thereafter activating at least one row of said phase-change memory cells;
wherein said programmable logic device is configured and programmed to store information in said phase-change memory, and to retrieve information from said phase-change memory at power-up.

2. The system of claim 1, where no regulator directly controls voltage of any of said bitlines when shorted.

3. The system of claim 1, where said read circuitry precharges bitlines of said first fraction for only a predetermined time before they are shorted together.

4. A method for operating a system which includes phase-change memory cells, comprising:
controlling output lines, and reading data inputs, using at least one programmable logic device;
reading and writing a phase-change memory with said programmable logic device;
at the start of a read operation, connecting a first predetermined fraction of the bitlines which connect to phase-change memory cells in a subarray of the phase-change memory to ground, and connecting a second predetermined fraction of the bitlines are to an internal supply voltage;
and thereafter shorting a plurality or all of the bitlines together, to rapidly provide a precharge voltage which is proportional to the internal supply voltage, with a ratio determined by said first and second predetermined fractions;
and thereafter activating at least one row of said phase-change memory cells to read data which is then communicated to said logic device.
